(19) United States
(12) Patent Application Publication
(10) Pub. No.: US 2026/0206354 A1
(43) Pub. Date: Jul. 16, 2026

(54) Semiconductor Light Receiving Device

(71) Applicant: NTT, Inc., Tokyo (JP)

(72) Inventors: Shoko Tatsumi, Musashino-shi, Tokyo (JP); Masahiro Nada, Musashino-shi, Tokyo (JP); Koichi Hadama, Musashino-shi, Tokyo (JP); Yasuhiko Nakanishi, Musashino-shi, Tokyo (JP); Atsushi Kanda, Musashino-shi, Tokyo (JP); Shohei Kosuga, Musashino-shi, Tokyo (JP); Takahiro Nakamura, Musashino-shi, Tokyo (JP)

(21) Appl. No.: 19/135,023

(22) PCT Filed: Dec. 14, 2022
(86) PCT No.: PCT/JP2022/046036

§ 371 Date: Jun. 2, 2025

(51) Int. Cl. H10F 39/90; H10F 30/223

(52) U.S. Cl. CPC H10F 39/90; H10F 30/223

(57) ABSTRACT

A semiconductor light-receiving element has a semiconductor laminate formed on an upper surface of a semiconductor substrate and in which a first semiconductor layer having a first conductivity type, a light absorption layer made of a semiconductor, and a second semiconductor layer having a second conductivity type are sequentially laminated, a first insulator layer formed on the upper surface of the semiconductor substrate so as to cover the semiconductor laminate, a first electrode and a second electrode formed on the upper surface of the first insulator layer, wirings connecting the first electrode and the second electrode to the first semiconductor layer and the second semiconductor layer, respectively, and a metal layer formed on the upper surface of the first insulator layer so as to cover the semiconductor laminate and the wirings and electrically separated from the first electrode and the second electrode.

### TECHNICAL FIELD

The present disclosure relates to a semiconductor light-receiving element.

### BACKGROUND ART

With an increase in communication traffic in recent years, there is a growing demand for faster and more sensitive optical receivers and smaller optical receivers to accommodate the optical receivers at higher density in order to improve an amount of communication per time. In the recent years, the optical receivers of a shape called TO-CAN and LC-ROSA have been widely used in 1ch optical receivers.

A photodiode (PD) is widely used element as the semiconductor light-receiving element for optical reception.

The photodiode is an element that performs photoelectric exchange by generating electrons and holes produced when light is absorbed under irradiation with light having energy equal to or higher than a band gap of a semiconductor. The most basic structure is called a pin photodiode (pin-PD). This structure is that an i-layer with a low impurity density is sandwiched between p-type and n-type semiconductors doped with high impurities density on both sides. When a reverse bias is applied to this pin structure, an electric field is generated in the i-layer, electrons and holes produced by light irradiation are swept, and a photocurrent is generated.

Since a differential voltage signal is required for an input of a digital signal processor (DSP) provided in the post-stage of the photodiode in the optical receiver, the photodiode cannot be directly connected to the digital signal processor. Normally, in the optical receiver, a transimpedance amplifier (TIA) is connected between the photodiode and the digital signal processor, an output current from the photodiode is amplified, the signal is inputted to the digital signal processor after converting to the differential signal, and signal processing is performed.

In the optical receiver of a type called TO-CAN and LC-ROSA widely used in optical communication, it is common to mount the photodiode and the digital signal processor on the same plane (refer to PTL 1 and NPL 1).

### CITATION LIST

### Patent Literature

[PTL 1] Japanese Patent Application Publication No. 2011-187607

### Non Patent Literature

[NPL 1] T. Ohno, Y. Muramoto, K. Sano, S. Kodama, and N. Shigekawa, “A CAN-type MIC-PD ROSA operating at 40-Gbit/s” ECOC 2010, Th. 10. D.2, Torino, Italy

### SUMMARY OF INVENTION

### Technical Problem

In the optical receiver of the above-described type, light is incident perpendicularly to the plane on which the photodiode and the transimpedance amplifier are mounted. In the optical receiver of this shape, if the photodiode is mounted on the transimpedance amplifier, the mounting area can be reduced, and need for further miniaturization can be met, but there is a case where interference between circuits due to electromagnetic induction occurs between the transimpedance amplifier and the photodiode.

As a cause of interference between circuits, induction through radio waves is listed in addition to electrostatic induction by an electric field and electromagnetic induction by a magnetic field. The induction from the circuit on the generation source side generates a noise current in the circuit on the reception side and causes deterioration in the frequency characteristics and reception sensitivity of the optical receiver. Since the induction is generated in the case of a circuit in which an AC current flows, both the photodiode and the transimpedance amplifier can become the noise generation source and the reception side. However, the intensity of the induced noise current increases in proportion to the current flowing through the generation source. Therefore, the noise current becomes larger when the transimpedance amplifier through which the amplified current flows is on the generation source side. Note that even if the insulator layer is interposed between the photodiode and the transimpedance amplifier, there is almost no effect of suppressing electric interference.

The present disclosure is proposed in view of the above-object of the present mentioned actual situation, and an object disclosure is to provide the semiconductor light-receiving element capable of achieving space saving for mounting without deteriorating reception sensitivity.

### Solution to Problem

In order to solve the above-mentioned problem, a semiconductor light-receiving element of the present disclosure includes a semiconductor laminate formed on an upper surface of a semiconductor substrate and in which a first semiconductor layer having a first conductivity type, a light absorption layer made of a semiconductor, and a second semiconductor layer having a second conductivity type are sequentially laminated, a first insulator layer formed on the upper surface of the semiconductor substrate so as to cover the semiconductor laminate, a first electrode and a second electrode formed on the upper surface of the first insulator layer, wirings connecting the first electrode and the second electrode to the first semiconductor layer and the second semiconductor layer, respectively, and a metal layer formed on the upper surface of the first insulator layer so as to cover the semiconductor laminate and the wirings and electrically separated from the first electrode and the second electrode.

In addition, a semiconductor light-receiving element of the present disclosure includes a semiconductor laminate formed on an upper surface of a semiconductor substrate and in which a first semiconductor layer having a first conductivity type, a light absorption layer made of a semiconductor, and a second semiconductor layer having a second conductivity type are sequentially laminated, a first insulator layer formed so as to cover a lower surface of the semiconductor substrate, and a metal layer formed on the lower surface of the first insulator layer so as to cover the semiconductor laminate and the wirings connected to the semiconductor laminate.

### Advantageous Effects of Invention

According to the present disclosure, it is possible to provide the semiconductor light-receiving element capable of achieving space saving for mounting without deteriorating reception sensitivity.

### BRIEF DESCRIPTION OF DRAWINGS

FIG. 1 is a cross-sectional view of a semiconductor light-receiving element according to a first embodiment.

FIG. 2 is a top view of the semiconductor light-receiving element according to the first embodiment.

FIG. 3 is a cross-sectional view showing a state in which the semiconductor light-receiving element is mounted on a transimpedance amplifier according to the first embodiment.

FIG. 4 is a top view of a semiconductor light-receiving element according to a first modification example of the first embodiment.

FIG. 5 is a top view of a semiconductor light-receiving element according to a second modification example of the first embodiment.

FIG. 6 is a cross-sectional view of a semiconductor light-receiving element according to a second embodiment.

FIG. 7 is a cross-sectional view showing a state in which the semiconductor light-receiving element is mounted on a transimpedance amplifier according to the second embodiment.

FIG. 8 is a cross-sectional view of a semiconductor light-receiving element according to a first modification example of the second embodiment.

FIG. 9 is a cross-sectional view of a semiconductor light-receiving element according to a second modification example of the second embodiment.

FIG. 10 is a cross-sectional view showing a state in which a semiconductor light-receiving element is mounted on a transimpedance amplifier according to a third embodiment.

FIG. 11 is a cross-sectional view of a semiconductor light-receiving element according to a modification example of the third embodiment.

FIG. 12 a cross-sectional view of semiconductor light-receiving element according to a fourth embodiment.

FIG. 13 is a cross-sectional view of a semiconductor light-receiving element according to a modification example of the fourth embodiment.

### DESCRIPTION OF EMBODIMENTS

Hereinafter, semiconductor light-receiving elements of the present embodiments will be described with reference to the drawings in order of the first embodiment to the fourth embodiment.

### First Embodiment

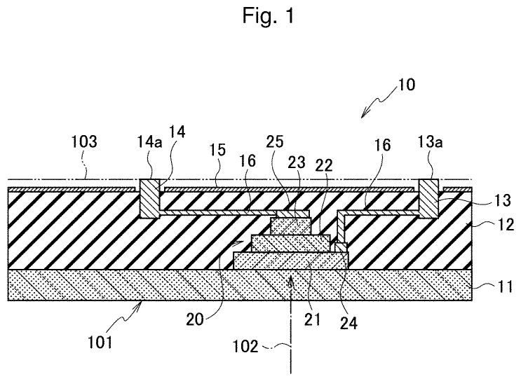

FIG. 1 is a cross-sectional view showing a semiconductor light-receiving element 10 according to a first embodiment. The semiconductor light-receiving element 10 according to the first embodiment is a back surface incident type for receiving incident light 102 incident from a back surface 101. The semiconductor light-receiving element 10 according to the first embodiment has a semiconductor substrate 11, a semiconductor laminate 20 in which a first semiconductor layer 21 having a first conductivity type, a light absorption layer 22 made of a semiconductor, and a second semiconductor layer 23 having a second conductivity type are sequentially laminated on an upper surface of the semiconductor substrate 11, and a first insulator layer 12 formed on the upper surface of the semiconductor substrate 11 so as to cover the semiconductor laminate 20. The semiconductor laminate 20 constitutes a pin photodiode.

In the semiconductor laminate 20, the light absorption layer 22 may be composed of a semiconductor having band gap energy corresponding to a wavelength of target light. The first semiconductor layer 21 and the second semiconductor layer 23 may be composed of a semiconductor having band gap energy larger than that of the semiconductor constituting the light absorption layer 22. The first semiconductor layer 21 and the second semiconductor layer 23 are each of conductivity types by introducing impurities, and the light absorption layer 22 may be in a state where the impurity concentration is lower than that of the first semiconductor layer 21 and the second semiconductor layer 23.

The semiconductor substrate 11 may be composed of semi-insulating InP. The first semiconductor layer 21 may be composed of n⁺-InP into which an n-type impurity is introduced with a high concentration. The light absorption layer 22 may be composed of undoped InGaAs. The second semiconductor layer 23 may be composed of p⁺-InGaAsP into which p-type impurity is introduced with the high concentration. In these cases, the above-mentioned first conductivity type becomes n-type and second conductivity type becomes p-type. The light absorption layer 22 and the second semiconductor layer 23 may be patterned into a predetermined shape, a part of the upper surface of the first semiconductor layer 21 may be exposed, and a first semiconductor electrode 24 may be formed in the exposed region. A second semiconductor electrode 25 is formed on the upper surface of the second semiconductor layer 23. The first insulator layer 12 may be composed of silicon oxide, silicon nitride, or the like.

The semiconductor light-receiving element 10 further has a first electrode 13 and a second electrode 14 formed on the upper surface of the first insulator layer 12, wirings 16 connecting the first electrode 13 and the second electrode 14 to the first semiconductor electrode 24 and the second semiconductor electrode 25, respectively, and a metal layer 15 formed on the upper surface of the first insulator layer 12 so as to cover the semiconductor laminate 20 and the wirings 16 and electrically separated from the first electrode 13 and the second electrode 14. The first electrode 13 and the second electrode 14 have a columnar shape and reach a predetermined depth from the upper surface of the first insulator layer 12. A first pad 13a and a second pad 14a are formed on the upper surfaces of the first electrode 13 and the second electrode 14, respectively, to secure a flat surface for connection. The first pad 13a and the second pad 14a may be plated. The first pad 13a and the second pad 14a are higher than the upper surface of the metal layer 15 and reach a predetermined height 103.

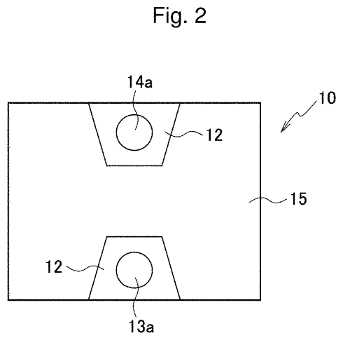

FIG. 2 is a top view of the semiconductor light-receiving element 10 according to the first embodiment. The first pad 13a and the second pad 14a are formed in a vicinity of a substantially central part of each of a pair of sides facing each other on the upper surface of the substantially rectangular first insulator layer 12. On the upper surface of the first insulator layer 12, the metal layer 15 is formed except substantially trapezoidal regions having long sides on a pair of sides facing each other surrounding the first pad 13a and the second pad 14a, respectively. The metal layer 15 is electrically separated from the first pad 13a and the second pad 14a, and the first electrode 13 and the second electrode 14 connected to the first pad 13a and the second pad 14a, respectively, by the substantially trapezoidal regions where the first insulator layer 12 is exposed. In addition, the metal layer 15 covers the semiconductor laminate 20 and the wirings 16 and electromagnetically shields them.

Here, thickness of the first insulator layer 12 will be described. If the first insulator layer 12 between the wirings 16 and the metal layer 15 is thin, a current component to be originally made to flow through the transimpedance amplifier 50 may flow through the metal layer 15. The input impedance Z_{in_m} from the wiring 16 to the metal layer 15 is expressed by Math. 1.

$${Z}_{in\_m} = j ( \frac{- 1}{j {ωεε}_{0} \frac{S}{d}} ) \qquad [ Math . 1 ]$$

In Math. 1, ω represents a frequency of a current, ε represents a dielectric constant of a vacuum, ε₀ represents a dielectric constant of a material of the first insulator layer 12, S represents an area of the wirings 16, and d represents the thickness of the first insulator layer 12. When the input impedance Z_{in_TIA} to the transimpedance amplifier 50 is set to 50Ω, if Z_{in_n} is 500Ω which is 10 times or more, the component flowing out to the metal layer 15 can be suppressed to 1/10 or less. Therefore, when ε₀, S, and d are adjusted in accordance with a required frequency band and Z_{in_m} is set to 500Ω or more, the semiconductor light-receiving element 10 in which current loss to the metal layer 15 is suppressed can be realized.

For example, when ω=25 GHz, ε=2.7 (dielectric constant of benzocyclobutene often used as an insulation material of a semiconductor product), ε₀=8.8×10⁻¹², S=2×10⁻⁹ m, and d=1 μm are satisfied, Z_{in_m}=842Ω is satisfied and the above-described condition is satisfied. That is, if the thickness of the first insulator layer 12 is 1 μm or more, the current loss to the metal layer 15 can be sufficiently suppressed. Such thickness of the first insulator layer 12 is similar to that of the semiconductor light-receiving element 10 according to another embodiment.

A manufacturing method of the semiconductor light-receiving element 10 according to the first embodiment will be described. The semiconductor laminate 20 deposited on the upper surface of the semiconductor substrate 11 is processed into a desired shape by wet etching or the like, and the first semiconductor electrode 24 and the second semiconductor electrode 25 are formed on the semiconductor laminate 20. A mirror or the like for returning the incident light 102 may be formed on the upper surface of the semiconductor laminate 20. Subsequently, a part of the first insulator layer 12 is formed on the upper surface of the semiconductor substrate 11 so as to cover the semiconductor laminate 20. Further, after the first electrode 13, the second electrode 14, and the wirings 16 are formed by plating, vapor deposition, or the like, the remaining part of the first insulator layer 12 is formed on upper parts. In the first insulator layer 12, the upper parts of the first electrode 13 and the second electrode 14 are removed by dry etching or the like. Finally, the metal layer 15, the first pad 13a, and the second pad 14a are formed by plating, vapor deposition, or the like. The first pad 13a and the second pad 14a are formed on the upper surfaces of the first electrode 13 and the second electrode 14, and made higher than the upper surface of the metal layer 15.

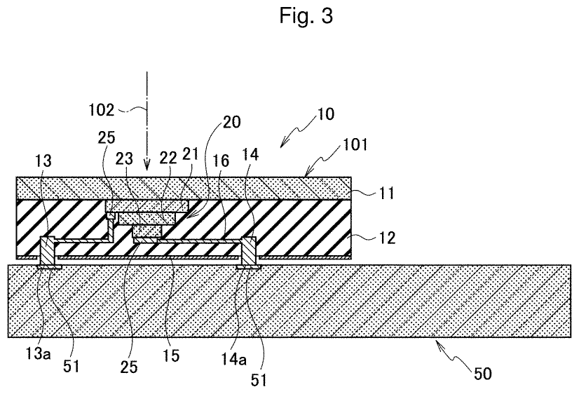

FIG. 3 is a cross-sectional view showing a state in which the semiconductor light-receiving element 10 is mounted on the transimpedance amplifier 50 according to the first embodiment. The semiconductor light-receiving element 10 according to the first embodiment is the back surface incident type for receiving incident light 102 from the back surface 101, and is flip-chip mounted on the upper surface of the transimpedance amplifier 50 so as to receive incident light 102 from above. The semiconductor light-receiving element 10 is vertically inverted so that its upper surface faces the upper surface of the transimpedance amplifier 50, and the first pad 13a and the second pad 14a are connected to input terminals 51 formed on the upper surface of the transimpedance amplifier 50, respectively. The connections between the first pad 13a and the second pad 14a and the input terminals 51 may be made by solder.

In the semiconductor light-receiving element 10 according to the first embodiment, the metal layer 15 is formed on the upper surface of the first insulator layer 12 so as to cover the semiconductor laminate 20 and the wirings 16. Therefore, the semiconductor laminate 20 and the wirings 16 of the semiconductor light-receiving element 10 are electrically shielded, and electromagnetic interference from the semiconductor laminate 20 and the wirings 16 is prevented from reaching the transimpedance amplifier 50. Therefore, deterioration of reception sensitivity caused by a noise current due to interference is suppressed, and space saving of a mounting area by flip-chip mounting of the semiconductor light-receiving element 10 on the transimpedance amplifier 50 can be achieved.

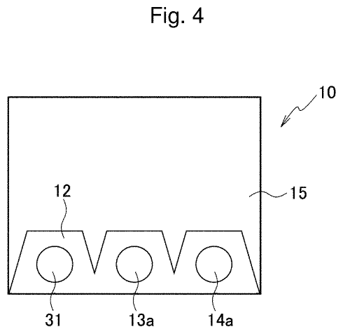

FIG. 4 is a top view of a first modification example of the semiconductor light-receiving element 10 according to the first embodiment. In the first modification example, a third pad 31, the first pad 13a, and the second pad 14a are formed in order along one side on the upper surface having a substantially rectangular shape. The third pad 31 may not be formed on the upper surface of the columnar electrode such as the first electrode 13 and the second electrode 14 like the first pad 13a and the second pad 14a, or may be formed on the upper surface of the first insulator layer 12. In addition, the third pad 31 may be connected to the first pad 13a or the second pad 14a. On the upper surface of the first insulator layer 12, the metal layer 15 is formed except a substantially trapezoidal region having a long side on one side surrounding the third pad 31, the first pad 13a, and the second pad 14a, respectively. The metal layer 15 is electrically separated from the third pad 31, the first pad 13a, and the second pad 14a and the first electrode 13 and the second electrode 14 connected to the first pad 13a and the second pad 14a, respectively, by the substantially trapezoidal regions where the first insulator layer 12 is exposed. In addition, the metal layer 15 covers the semiconductor laminate 20 and the wirings 16 and electromagnetically shields them.

Therefore, the semiconductor light-receiving element 10 according to the first modification example can both suppress the deterioration of the reception sensitivity caused by the noise current due to interference, and achieve space saving of the mounting area by flip-chip mounting the semiconductor light-receiving element 10 on the transimpedance amplifier 50, similarly to the semiconductor light-receiving element 10 according to the first embodiment. In addition, in the semiconductor light-receiving element 10 according to the first modification example, the third pad 31 is provided on the upper surface of the first insulator layer 12, and the number of pads is secured to facilitate design of wiring and the like. Note that in addition to the third pad 31, pads provided on the upper surface of the first insulator layer 12 may be further increased.

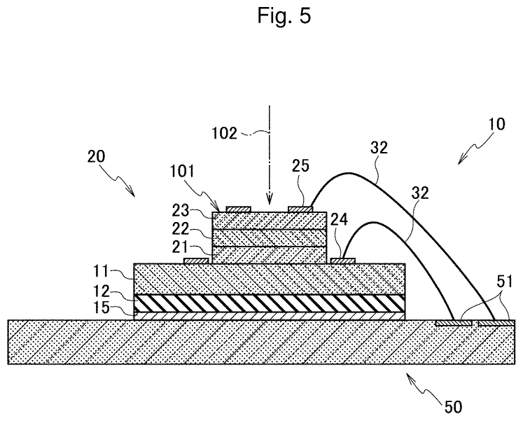

FIG. 5 is a cross-sectional view showing a semiconductor light-receiving element 10 according to a second modification example of the first embodiment. The semiconductor light-receiving element 10 according to the second modification example is a front surface incident type for receiving incident light 102 incident from above. The semiconductor light-receiving element 10 according to the second modification example has the semiconductor substrate 11, and the semiconductor laminate 20 in which the first semiconductor layer 21 having the first conductivity type, the light absorption layer 22 made of the semiconductor, and the second semiconductor layer 23 having the second conductivity type are sequentially laminated on the upper surface of the semiconductor substrate 11. The semiconductor laminate 20 constitutes the pin photodiode.

In the semiconductor laminate 20, the light absorption layer 22 may be composed of a semiconductor having band gap energy corresponding to a wavelength of target light. The first semiconductor layer 21 and the second semiconductor layer 23 may be composed of a semiconductor having band gap energy larger than that of the semiconductor constituting the light absorption layer 22. The first semiconductor layer 21 and the second semiconductor layer 23 are each of conductivity types by introducing impurities, and the light absorption layer 22 may be in a state where the impurity concentration is lower than that of the first semiconductor layer 21 and the second semiconductor layer 23.

The semiconductor substrate 11 may be composed of semi-insulating InP. The first semiconductor layer 21 may be composed of n⁺-InP into which the n-type impurity is introduced with the high concentration. The light absorption layer 22 may be composed of undoped InGaAs. The second semiconductor layer 23 may be composed of p⁺-InGaAsP into which the p-type impurity is introduced with the high concentration. In these cases, the above-mentioned first conductivity type becomes n-type and second conductivity type becomes p-type. The light absorption layer 22 and the second semiconductor layer 23 may be patterned into a predetermined shape, a part of the upper surface of the first semiconductor layer 21 may be exposed, and the first semiconductor electrode 24 may be formed in the exposed region. The second semiconductor electrode 25 is formed on the upper surface of the second semiconductor layer 23.

The semiconductor light-receiving element 10 according to the second modification example further has the first insulator layer 12 and the metal layer 15 which are sequentially laminated on the lower surface of the semiconductor substrate 11. The metal layer 15 is formed so as to cover the semiconductor laminate 20. The metal layer 15 may be formed so as to cover the lower surface of the semiconductor substrate 11, or may be formed so as not to interfere with the input terminals 51 of the transimpedance amplifier 50 except for a partial region.

In the semiconductor light-receiving element 10 according to the second modification example, the lower surface of the metal layer 15 is bonded to the upper surface of the transimpedance amplifier 50. Then, the first semiconductor electrode 24 and the second semiconductor electrode 25 are connected to the input terminals 51 of the transimpedance amplifier 50 by wires 32, respectively. Therefore, also in the semiconductor light-receiving element 10 according to the second modification example, the semiconductor laminate 20 is electrically shielded by the intervening metal layer 15, and electromagnetic interference from the semiconductor laminate 20 is prevented from reaching the transimpedance amplifier 50. Therefore, deterioration of reception sensitivity caused by the noise current due to interference is suppressed.

A manufacturing method of the semiconductor light-receiving element 10 according to the second modification example will be described. On the upper surface of the semiconductor substrate 11, the deposited semiconductor laminate 20 is processed into a desired shape by wet etching or the like to form the first semiconductor electrode 24 and the second semiconductor electrode 25. On the lower surface of the semiconductor substrate 11, after the first insulator layer 12 is formed, the metal layer 15 is formed by vapor deposition, plating, or the like. The lower surface of the metal layer 15 is bonded to the upper surface of the transimpedance amplifier 50 by silver paste or the like. Then, the first semiconductor electrode 24 and the second semiconductor electrode 25 are connected to the input terminals 51 of the transimpedance amplifier 50 by the wires 32.

Note that in the first embodiment, as shown in FIG. 2 and FIG. 4, arrangement of the metal layer 15 in which the first insulator layer 12 is exposed in the trapezoidal shape around the first pad 13a, the second pad 14a, and the like is shown, but this is not limited thereto. As long as the metal layer 15 is electrically separated from the first pad 13a, the second pad 14a, the first electrode 13, and the second electrode 14, and covers the semiconductor laminate 20 and the wiring 16, other forming patterns may be arranged.

### Second Embodiment

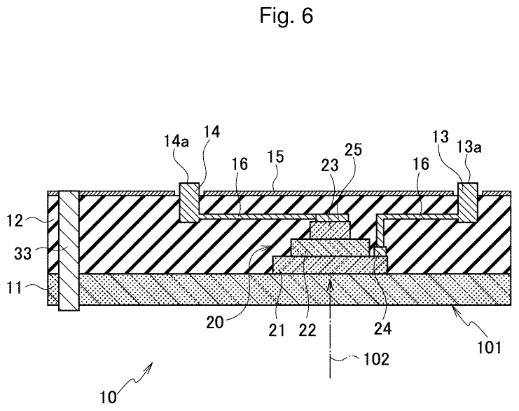

FIG. 6 is a cross-sectional view showing a semiconductor light-receiving element 10 according to a second embodiment. The semiconductor light-receiving element 10 according to the second embodiment is the back surface incident type for receiving incident light 102 incident from the back surface 101. The semiconductor light-receiving element 10 according to the second embodiment has the semiconductor substrate 11, the semiconductor laminate 20 in which the first semiconductor layer 21 having a first conductivity type, the light absorption layer 22 made of a semiconductor, and the second semiconductor layer 23 having a second conductivity type are sequentially laminated on the upper surface of the semiconductor substrate 11, and the first insulator layer 12 formed on the upper surface of the semiconductor substrate 11 so as to cover the semiconductor laminate 20. The semiconductor laminate 20 constitutes the pin photodiode.

The light absorption layer 22 may be made of semiconductor having band gap energy corresponding to a wavelength of target light. The first semiconductor layer 21 and the second semiconductor layer 23 may be composed of a semiconductor having band gap energy larger than that of the semiconductor constituting the light absorption layer 22. The first semiconductor layer 21 and the second semiconductor layer 23 are each of conductivity types by introducing impurities, and the light absorption layer 22 may be in a state where the impurity concentration is of lower than that the first semiconductor layer 21 and the second semiconductor layer 23.

The semiconductor substrate 11 may be composed of semi-insulating InP. The first semiconductor layer 21 may be composed of n⁺-InP into which the n-type impurity is introduced with the high concentration. The light absorption layer 22 may be composed of undoped InGaAs. The second semiconductor layer 23 may be composed of p⁺-InGaAsP into which the p-type impurity is introduced with the high concentration. In these cases, the above-mentioned first conductivity type becomes n-type and second conductivity type becomes p-type. The light absorption layer 22 and the second semiconductor layer 23 may be patterned into a predetermined shape, a part of the upper surface of the first semiconductor layer 21 may be exposed, and the first semiconductor electrode 24 may be formed in the exposed region. The second semiconductor electrode 25 is formed on the upper surface of the second semiconductor layer 23. The first insulator layer 12 may be composed of silicon oxide, silicon nitride, or the like.

The semiconductor light-receiving element 10 further has the first electrode 13 and the second electrode 14 formed on the upper surface of the first insulator layer 12, wirings 16 connecting the first electrode 13 and the second electrode 14 to the first semiconductor 24 electrode and the second semiconductor electrode 25, respectively, and the metal layer 15 formed on the upper surface of the first insulator layer 12 so as to cover the semiconductor laminate 20 and the wirings 16 and electrically separated from the first electrode 13 and the second electrode 14. The first electrode 13 and the second electrode 14 have the columnar shape and reach a predetermined depth from the upper surface of the first insulator layer 12. The first pad 13a and the second pad 14a are formed on the upper surfaces of the first electrode 13 and the second electrode 14, respectively, to secure the flat surface for connection. The first pad 13a and the second pad 14a may be plated. The first pad 13a and the second pad 14a are higher than the upper surface of the metal layer 15 and reach a predetermined height 103.

Also, in the semiconductor light-receiving element 10 according to the second embodiment, the metal layer 15 covering the semiconductor laminate 20 and the wirings 16 and electrically separated from the first pad 13a and the second pad 14a, the first electrode 13, and the second electrode 14 is formed on the upper surface of the first insulator layer 12. The metal layer 15 electromagnetically shields the semiconductor laminate 20 and the wirings 16. In addition, a through via 33 penetrating the semiconductor substrate 11, the first insulator layer 12, and the metal layer 15 is formed, and the through via 33 is connected to the metal layer 15. The through via 33 protrudes from the lower surface of the semiconductor substrate 11.

A manufacturing method of the semiconductor light-receiving element 10 according to the second embodiment will be described. The semiconductor laminate 20 deposited on the upper surface of the semiconductor substrate 11 is processed into a desired shape by wet etching or the like, and the first semiconductor electrode 24 and the second semiconductor electrode 25 are formed on the semiconductor laminate 20. The mirror or the like for returning the incident light 102 may be formed on the upper surface of the semiconductor laminate 20. Subsequently, a part of the first insulator layer 12 is formed on the upper surface of the semiconductor substrate 11 so as to cover the semiconductor laminate 20. Further, after the first electrode 13, the second electrode 14, and the wirings 16 are formed by plating, vapor deposition, or the like, the remaining part of the first insulator layer 12 is formed on the upper parts. In the first insulator layer 12, the upper parts of the first electrode 13 and the second electrode 14 are removed by dry etching or the like. Finally, the metal layer 15, the first pad 13a, and the second pad 14a are formed by plating, vapor deposition, or the like. The first pad 13a and the second pad 14a are formed on the upper surfaces of the first electrode 13 and the second electrode 14, and made higher than the upper surface of the metal layer 15. Thereafter, the through hole is formed through the semiconductor substrate 11, the first insulator layer 12, and the metal layer 15 by dry etching, and the through via 33 is formed by filling the through hole with metal.

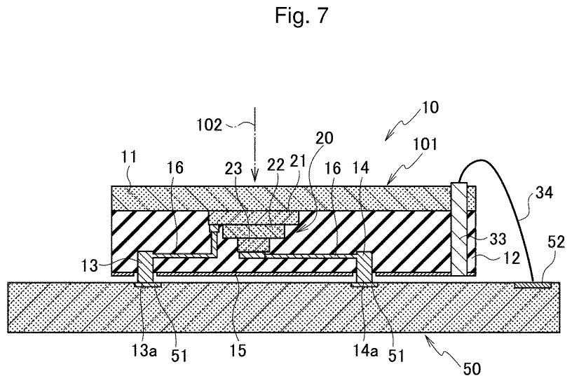

FIG. 7 is a cross-sectional view showing a state in which a semiconductor light-receiving element 10 is mounted on a transimpedance amplifier 50 according to the second embodiment. The semiconductor light-receiving element 10 according to the second embodiment is the back surface incident type for receiving incident light 102 from the back surface 101, and is flip-chip mounted on the upper surface of the transimpedance amplifier 50 so as to receive incident light 102 from above. The semiconductor light-receiving element 10 is vertically inverted so that its upper surface faces the upper surface of the transimpedance amplifier 50, and the first pad 13a and the second pad 14a are connected to the input terminals 51 formed on the upper surface of the transimpedance amplifier 50, respectively. The connections between the first pad 13a and the second pad 14a and the input terminals 51 may be made by solder. In addition, the through via 33 protruding from the lower surface of the semiconductor substrate 11 is connected to a ground terminal 52 of the transimpedance amplifier 50 by a wire 34.

In the semiconductor light-receiving element 10 according to the second embodiment, the metal layer 15 is formed on the upper surface of the first insulator layer 12 so as to cover the semiconductor laminate 20 and the wirings 16. Therefore, the semiconductor laminate 20 and the wirings 16 of the semiconductor light-receiving element 10 are electrically shielded, and electromagnetic interference from the semiconductor laminate 20 and the wirings 16 is prevented from reaching the transimpedance amplifier 50. Therefore, deterioration of reception sensitivity caused by the noise current due to interference is suppressed, and space saving of the mounting area can be achieved by flip-chip mounting the semiconductor light-receiving element 10 on the transimpedance amplifier 50.

In addition, in the semiconductor light-receiving element 10 according to the second embodiment, the metal layer 15 is connected to the ground terminal 52 of the transimpedance amplifier 50 through the through via 33 and the wire 34. Since the metal layer 15 is maintained at the ground potential, radiation of electromagnetic waves through the metal layer 15 can be suppressed, and electromagnetic shielding the semiconductor laminate 20 can be secured. Further, in the second embodiment, the connection by the wire 34 becomes possible and the connection with other members is facilitated by providing the through via 33. In addition, the connection by the wire 34 is not limited to one point, but can be connected to a plurality of positions.

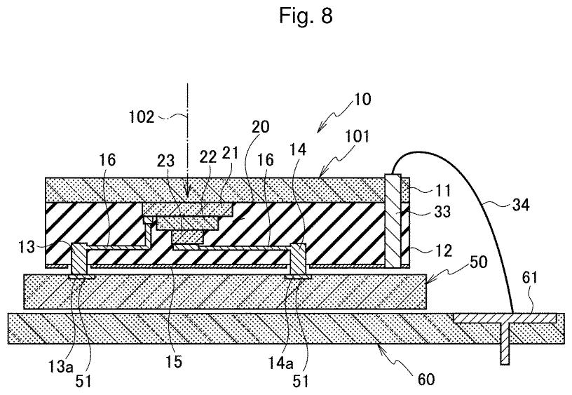

FIG. 8 is a cross-sectional view showing a first modification example of a semiconductor light-receiving element 10 according to the second embodiment. The semiconductor light-receiving element 10 according to the second embodiment is the back surface incident type for receiving incident light 102 from the back surface 101, and is flip-chip mounted on the upper surface of the transimpedance amplifier 50 so as to receive incident light 102 from above, and the transimpedance amplifier 50 in which the semiconductor light-receiving element 10 is mounted is further accommodated in a package 60. The semiconductor light-receiving element 10 is vertically inverted so that its upper surface faces the upper surface of the transimpedance amplifier 50, and the first pad 13a and the second pad 14a are connected to the input terminals 51 formed on the upper surface of the transimpedance amplifier 50, respectively. The connections between the first pad 13a and the second pad 14a and the input terminals 51 may be made by solder. In the first modification example, the through via 33 protruding from the lower surface of the semiconductor substrate 11 is connected to a ground terminal 61 of the package 60 by a wire 34.

In the semiconductor light-receiving element 10 according to the first modification example, the metal layer 15 is formed on the upper surface of the first insulator layer 12 so as to cover the semiconductor laminate 20 and the wirings 16. Therefore, the semiconductor laminate 20 and the wirings 16 of the semiconductor light-receiving element 10 are electrically shielded, and electromagnetic interference from the semiconductor laminate 20 and the wirings 16 is prevented from reaching the transimpedance amplifier 50. Therefore, deterioration of reception sensitivity caused by the noise current due to interference is suppressed, and space saving of the mounting area can be achieved by flip-chip mounting the semiconductor light-receiving element 10 on the transimpedance amplifier 50.

In addition, in the semiconductor light-receiving element 10 according to the first modification example, the metal layer 15 is connected to the ground terminal 61 of the package 60 through the through via 33 and the wire 34. Since the metal layer 15 is maintained at the ground potential, radiation of electromagnetic waves through the metal layer 15 can be suppressed, and electromagnetic shielding of the semiconductor laminate 20 and the wirings 16 can be secured. Further, in the first modification example, the connection by the wire 34 becomes possible and the connection with other members is facilitated by providing the through via 33. In addition, the connection by the wire 34 is not limited to one point, but can be connected to a plurality of positions.

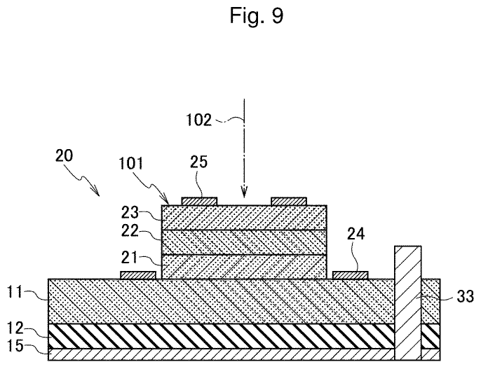

FIG. 9 is a cross-sectional view showing a semiconductor light-receiving element 10 according a second modification example of the second embodiment. The semiconductor light-receiving element 10 according to the second modification example is the front surface incident type for receiving incident light 102 incident from above. The semiconductor light-receiving element 10 according to the second modification example has the semiconductor substrate 11, and the semiconductor laminate 20 in which the first semiconductor layer 21 having the first conductivity type, the light absorption layer 22 made of the semiconductor, and the second semiconductor layer 23 having the second conductivity type are sequentially laminated on the upper surface of the semiconductor substrate 11. The semiconductor laminate 20 constitutes the pin photodiode.

In the semiconductor laminate 20, the light absorption layer 22 may be composed of a semiconductor having band gap energy corresponding to a wavelength of target light. The first semiconductor layer 21 and the second semiconductor layer 23 may be composed of a semiconductor having band gap energy larger than that of the semiconductor constituting the light absorption layer 22. The first semiconductor layer 21 and the second semiconductor layer 23 are each of conductivity types by introducing impurities, and the light absorption layer 22 may be in a state where the impurity concentration is lower than that of the first semiconductor layer 21 and the second semiconductor layer 23.

The semiconductor substrate 11 may be composed of semi-insulating InP. The first semiconductor layer 21 may be composed of n⁺-InP into which the n-type impurity is introduced with the high concentration. The light absorption layer 22 may be composed of undoped InGaAs. The second semiconductor layer 23 may be composed of p⁺-InGaAsP into which the p-type impurity is introduced with the high concentration. In these cases, the above-described first conductivity type becomes n-type and second conductivity type becomes p-type. The light absorption layer 22 and the second semiconductor layer 23 may be patterned into a predetermined shape, a part of the upper surface of the first semiconductor layer 21 may be exposed, and the first semiconductor electrode 24 may be formed in the exposed region. The second semiconductor electrode 25 is formed on the upper surface of the second semiconductor layer 23.

The semiconductor light-receiving element 10 according to the second modification example further has the first insulator layer 12 and the metal layer 15 which are sequentially laminated on the lower surface of the semiconductor substrate 11. The metal layer 15 is formed so as to cover the semiconductor laminate 20. The metal layer 15 may be formed so as to cover the lower surface of the semiconductor substrate 11, or may be formed so as not to interfere with the input terminals 51 of the transimpedance amplifier 50 except for a partial region. In the second modification example, a through via 33 is further provided which penetrates the semiconductor substrate 11 and the first insulator layer 12. The through via 33 is higher than the upper surface of the semiconductor substrate 11, and the lower surface of the through via 33 is connected to the metal layer 15.

In the semiconductor light-receiving element 10 according to the second modification example, the lower surface of the metal layer 15 is bonded to the upper surface of the transimpedance amplifier 50. Then, the first semiconductor electrode 24 and the second semiconductor electrode 25 are connected to the input terminals 51 of the transimpedance amplifier 50 by wires, respectively. Therefore, also in the semiconductor light-receiving element 10 according to the second modification example, the semiconductor laminate 20 is electrically shielded by the intervening metal layer 15, and electromagnetic interference from the semiconductor laminate 20 is prevented from reaching the transimpedance amplifier 50. Therefore, deterioration of reception sensitivity caused by the noise current due to interference is suppressed.

In addition, in the semiconductor light-receiving element 10 according to the second modification example, the metal layer 15 is connected to the ground terminal 52 of the transimpedance amplifier 50 through the through via 33 and the wire 34. Since the metal layer 15 is maintained at the ground potential, radiation of electromagnetic waves through the metal layer 15 can be suppressed, and electromagnetic shielding of the semiconductor laminate 20 and the wire can be secured. Further, in the second modification example, the connection by the wire 34 becomes possible and the connection with other members is facilitated by providing the through via 33. In addition, the connection by the wire 34 is not limited to one point, but can be connected to a plurality of positions.

A manufacturing method of the semiconductor light-receiving element 10 according to the second modification example will be described. On the upper surface of the semiconductor substrate 11, the deposited semiconductor laminate 20 is processed into a desired shape by wet etching or the like to form the first semiconductor electrode 24 and the second semiconductor electrode 25. On the lower surface of the semiconductor substrate 11, after the first insulator layer 12 is formed, the metal layer 15 is formed by vapor deposition, plating, or the like. Thereafter, the through hole is formed through the semiconductor substrate 11, the first insulator layer 12, and the metal layer 15 by dry etching, and the through via 33 is formed by filling the through hole with metal. Further, the lower surface of the metal layer 15 is bonded to the upper surface of the transimpedance amplifier 50 by silver paste or the like. Then, the first semiconductor electrode 24 and the second semiconductor electrode 25 are connected to the input terminals 51 of the transimpedance amplifier 50 by the wires 32.

### Third Embodiment

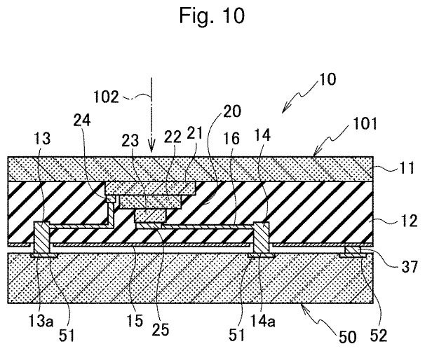

FIG. 10 is a cross-sectional view showing a state in which a semiconductor light-receiving element 10 is mounted on a transimpedance amplifier 50 according to a third embodiment. The semiconductor light-receiving element 10 according to the third embodiment is the back surface incident type for receiving incident light 102 incident from the back surface 101. In FIG. 10, the semiconductor light-receiving element 10 according to the third embodiment is flip-chip mounted on the upper surface of the transimpedance amplifier 50 so as to receive incident light 102 from above. Note that since the semiconductor light-receiving element 10 according to the third embodiment is flip-chip mounted on the transimpedance amplifier 50, the semiconductor light-receiving element 10 has its upper surface directed downward.

The semiconductor light-receiving element 10 according to the third embodiment has the semiconductor substrate 11, the semiconductor laminate 20 in which the first semiconductor layer 21 having a first conductivity type, the light absorption layer 22 made of a semiconductor, and the second semiconductor layer 23 having a second conductivity type are sequentially laminated on the upper surface of the semiconductor substrate 11, and the first insulator layer 12 formed on the upper surface of the semiconductor substrate 11 so as to cover the semiconductor laminate 20. The semiconductor laminate 20 constitutes the pin photodiode.

The light absorption layer 22 may be composed of a semiconductor having band gap energy corresponding to a wavelength of target light. The first semiconductor layer 21 and the second semiconductor layer 23 may be composed of a semiconductor having band gap energy larger than that of the semiconductor constituting the light absorption layer 22. The first semiconductor layer 21 and the second semiconductor layer 23 are each of conductivity types by introducing impurities, and the light absorption layer 22 may be in a state where the impurity concentration is lower than that of the first semiconductor layer 21 and the second semiconductor layer 23.

The semiconductor substrate 11 may be composed of semi-insulating InP. The first semiconductor layer 21 may be composed of n⁺-InP into which the n-type impurity is introduced with the high concentration. The light absorption layer 22 may be composed of undoped InGaAs. The second semiconductor layer 23 may be composed of p⁺-InGaAsP into which the p-type impurity is introduced with the high concentration. In these cases, the above-mentioned first conductivity type becomes n-type and second conductivity type becomes p-type. The light absorption layer 22 and the second semiconductor layer 23 may be patterned into a predetermined shape, a part of the upper surface of the first semiconductor layer 21 may be exposed, and the first semiconductor electrode 24 may be formed in the exposed region. The second semiconductor electrode 25 is formed on the upper surface of the second semiconductor layer 23. The first insulator layer 12 may be composed of silicon oxide, silicon nitride, or the like.

The semiconductor light-receiving element 10 has the first electrode 13 and the second electrode 14 formed on the upper surface of the first insulator layer 12, the wirings 16 connecting the first electrode 13 and the second electrode 14 to the first electrode semiconductor 24 and the second semiconductor electrode 25, respectively, and the metal layer formed on the upper surface of the first insulator layer 12 so as to cover the semiconductor laminate 20 and the wirings 16 and electrically separated from the first electrode 13 and the second electrode 14. The first electrode 13 and the second electrode 14 have the columnar shape and reach a predetermined depth from the upper surface of the first insulator layer 12. A first pad 13a and a second pad 14a are formed on the upper surfaces of the first electrode 13 and the second electrode 14, respectively, to secure the flat surface for connection. The first pad 13a and the second pad 14a may be plated. The first pad 13a and the second pad 14a are higher than the upper surface of the metal layer 15 and reach a predetermined height 103.

Also, in the semiconductor light-receiving element 10 according to the third embodiment, the metal layer 15 covering the semiconductor laminate 20 and the wirings 16 and electrically separated the first pad 13a and the second pad 14a, the first electrode 13, and the second electrode 14 is formed on the upper surface of the first insulator layer 12. The metal layer 15 electromagnetically shields the semiconductor laminate 20 and the wirings 16. In addition, a pad 37 having a predetermined height is formed on the upper surface of the metal layer 15. The pad 37 may have the same height as the first pad 13a and the second pad 14a.

In the semiconductor light-receiving element 10, the first pad 13a and the second pad 14a are connected to the input terminals 51 formed on the upper surface of the transimpedance amplifier 50, respectively. In addition, the pad 37 is also connected to the ground terminal 52 formed on the upper surface of the transimpedance amplifier 50. The connection between the first pad 13a and the second pad 14a and the input terminal 51, the pad 37, and the ground terminal 52 may be made by solder.

In the semiconductor light-receiving element 10 according to the third embodiment, the metal layer 15 is formed on the upper surface of the first insulator layer 12 so as to cover the semiconductor laminate 20 and the wirings 16.

Therefore, the semiconductor laminate 20 and the wirings 16 of the semiconductor light-receiving element 10 are electrically shielded, and electromagnetic interference from the semiconductor laminate 20 and the wirings 16 is prevented from reaching the transimpedance amplifier 50. Therefore, deterioration of reception sensitivity caused by the noise current due to interference is suppressed, and space saving of the mounting area can be achieved by flip-chip mounting the semiconductor light-receiving element 10 on the transimpedance amplifier 50.

In addition, in the semiconductor light-receiving element 10 according to the third embodiment, the metal layer 15 is connected to the ground terminal 52 of the transimpedance amplifier 50 through the pad 37. Since the metal layer 15 is maintained at the ground potential, radiation of electromagnetic waves through the metal layer 15 can be suppressed, and electromagnetic shielding of the semiconductor laminate 20 and the wirings 16 can be secured. Further, according to the third embodiment, since the pad 37 is formed on the upper surface of the metal layer 15, it can be easily connected by being overlapped with the ground terminal 52 of the transimpedance amplifier 50.

A manufacturing method of the semiconductor light-receiving element 10 according to the third embodiment will be described. The semiconductor laminate 20 deposited on the upper surface of the semiconductor substrate 11 is processed into a desired shape by wet etching or the like, and the first semiconductor electrode 24 and the second semiconductor electrode 25 are formed on the semiconductor laminate 20. The mirror or the like for returning the incident light 102 may be formed on the upper surface of the semiconductor laminate 20. Subsequently, a part of the first insulator layer 12 is formed on the upper surface of the semiconductor substrate 11 so as to cover the semiconductor laminate 20. Further, after the first electrode 13, the second electrode 14, and the wirings 16 are formed by plating, vapor deposition, or the like, the remaining part of the first insulator layer 12 is formed on the upper parts. In the first insulator layer 12, the upper parts of the first electrode 13 and the second electrode 14 are removed by dry etching or the like. The metal layer 15, the first pad 13a, and the second pad 14a are formed by plating, vapor deposition, or the like. The first pad 13a and the second pad 14a are formed on the upper surfaces of the first electrode 13 and the second electrode 14, and made higher than the upper surface of the metal layer 15. Finally, the pad 37 is formed on the upper surface of the metal layer 15 by plating, vapor deposition, or the like.

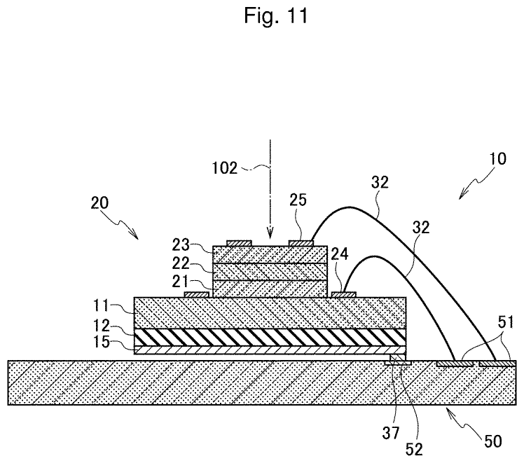

FIG. 11 is a cross-sectional view showing a semiconductor light-receiving element 10 according a modification example of the third embodiment. The semiconductor light-receiving element 10 according to the modification example is the front surface incident type for receiving incident light 102 incident from above. The semiconductor light-receiving element 10 according to the third modification example has the semiconductor substrate 11, and the semiconductor laminate 20 in which the first semiconductor layer 21 having a first conductivity type, the light absorption layer 22 made of a semiconductor, and the second semiconductor layer 23 having a second conductivity type are sequentially laminated on the upper surface of the semiconductor substrate 11. The semiconductor laminate 20 constitutes the pin photodiode.

In the semiconductor laminate 20, the light absorption layer 22 may be composed of a semiconductor having band gap energy corresponding to a wavelength of target light. The first semiconductor layer 21 and the second semiconductor layer 23 may be composed of a semiconductor having band gap energy larger than that of the semiconductor constituting the light absorption layer 22. The first semiconductor layer 21 and the second semiconductor layer 23 are each of conductivity types by introducing impurities, and the light absorption layer 22 may be in a state where the impurity concentration is lower than that of the first semiconductor layer 21 and the second semiconductor layer 23.

The semiconductor substrate 11 may be composed of semi-insulating InP. The first semiconductor layer 21 may be composed of n⁺-InP into which the n-type impurity is introduced with the high concentration. The light absorption layer 22 may be composed of undoped InGaAs. The second semiconductor layer 23 may be composed of p⁺-InGaAsP into which the p-type impurity is introduced with the high concentration. In these cases, the above-mentioned first conductivity type becomes n-type and second conductivity type becomes p-type. The light absorption layer 22 and the second semiconductor layer 23 may be patterned into a predetermined shape, a part of the upper surface of the first semiconductor layer 21 may be exposed, and the first semiconductor electrode 24 may be formed in the exposed region. The second semiconductor electrode 25 is formed on the upper surface of the second semiconductor layer 23.

The semiconductor light-receiving element 10 according to the modification example further has the first insulator layer 12 and the metal layer 15 which are sequentially laminated on the lower surface of the semiconductor substrate 11. The metal layer 15 is formed so as to cover the semiconductor laminate 20. The metal layer 15 may be formed so as to cover the lower surface of the semiconductor substrate 11, or may be formed so as not to interfere with the input terminals 51 of the transimpedance amplifier 50 except for a partial region. In the modification example, the pad 37 having a predetermined height is formed on the lower surface of the metal layer 15.

In the semiconductor light-receiving element 10 according to the modification example, the lower surface of the metal layer 15 is bonded so as to face the upper surface of the transimpedance amplifier 50. Then, the first semiconductor electrode 24 and the second semiconductor electrode 25 are connected to the input terminals 51 of the transimpedance amplifier 50 by wires 32, respectively. Therefore, also in the semiconductor light-receiving element 10 according to the modification example, the semiconductor laminate 20 is electrically shielded by the intervening metal layer 15, and electromagnetic interference from the semiconductor laminate 20 is prevented from reaching the transimpedance amplifier 50. Therefore, deterioration of reception sensitivity caused by the noise current due to interference is suppressed.

In addition, in the semiconductor light-receiving element 10 according to the second embodiment, the pad 37 is connected to the ground terminal 52 formed on the upper surface of the transimpedance amplifier 50. The connection between the pad 37 and the ground terminal 52 may be made by solder. Since the metal layer 15 is maintained at the ground potential, radiation of electromagnetic waves through the metal layer 15 can be suppressed, and electromagnetic shielding of the semiconductor laminate 20 can be secured.

A manufacturing method of the semiconductor light-receiving element 10 according to the modification example will be described. On the upper surface of the semiconductor substrate 11, the deposited semiconductor laminate 20 is processed into a desired shape by wet etching or the like to form the first semiconductor electrode 24 and the second semiconductor electrode 25. On the lower surface of the semiconductor substrate 11, after the first insulator layer 12 is formed, the metal layer 15 is formed by vapor deposition, plating, or the like. Further, the pad 37 is formed on the upper surface of the metal layer 15 by vapor deposition, plating, or the like. Then, the upper surface of the metal layer 15 is installed so as to face the upper surface of the transimpedance amplifier 50, and the upper surface of the pad 37 is connected to the ground terminal 52 formed on the upper surface of the transimpedance amplifier 50 by solder or the like. In addition, the first electrode semiconductor 24 and the second semiconductor electrode 25 are connected to the input terminals 51 of the transimpedance amplifier 50 by the wires 34.

### Fourth Embodiment

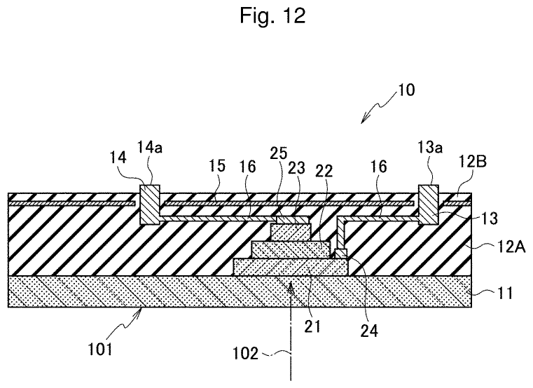

FIG. 12 is a cross-sectional view showing a semiconductor light-receiving element 10 according to a fourth embodiment. The semiconductor light-receiving element 10 according to the fourth embodiment is the back surface incident type for receiving incident light 102 incident from the back surface 101. The semiconductor light-receiving element 10 according to the fourth embodiment has the semiconductor substrate 11, the semiconductor laminate 20 in which the first semiconductor layer 21 having a first conductivity type, the light absorption layer 22 made of a semiconductor, and the second semiconductor layer 23 having a second conductivity type are sequentially laminated on the upper surface of the semiconductor substrate 11, and a first insulator layer 12A formed on the upper surface of the semiconductor substrate 11 so as to cover the semiconductor laminate 20. The semiconductor laminate 20 constitutes the pin photodiode.

In the semiconductor laminate 20, the light absorption layer 22 may be composed of a semiconductor having band gap energy corresponding to a wavelength of target light. The first semiconductor layer 21 and the second semiconductor layer 23 may be composed of a semiconductor having band gap energy larger than that of the semiconductor constituting the light absorption layer 22. The first semiconductor layer 21 and the second semiconductor layer 23 are each of conductivity types by introducing impurities, and the light absorption layer 22 may be in a state where the impurity concentration is lower than that of the first semiconductor layer 21 and the second semiconductor layer 23.

The semiconductor substrate 11 may be composed of semi-insulating InP. The first semiconductor layer 21 may be composed of n⁺-InP into which the n-type impurity is introduced with the high concentration. The light absorption layer 22 may be composed of undoped InGaAs. The second semiconductor layer 23 may be composed of p⁺-InGaAsP into which the p-type impurity is introduced with the high concentration. In these cases, the above-mentioned first conductivity type becomes n-type and second conductivity type becomes p-type. The light absorption layer 22 and the second semiconductor layer 23 may be patterned into a predetermined shape, a part of the upper surface of the first semiconductor layer 21 may be exposed, and the first semiconductor electrode 24 may be formed in the exposed region. The second semiconductor electrode 25 is formed on the upper surface of the second semiconductor layer 23. The first insulator layer 12A may be composed of silicon oxide, silicon nitride, or the like.

The semiconductor light-receiving element 10 further has the first electrode 13 and the second electrode 14 formed on the upper surface of the first insulator layer 12, the wirings 16 connecting the first electrode 13 and the second electrode 14 to the first semiconductor electrode 24 and the second semiconductor electrode 25, respectively, and the metal layer 15 formed on the upper surface of the first insulator layer 12A so as to cover the semiconductor laminate 20 and the wirings 16 and electrically separated from the first electrode 13 and the second electrode 14, and a second insulator layer 12B covering the first insulator layer 12A and the metal layer 15. The first electrode 13 and the second electrode 14 have the columnar shape, and reach a predetermined depth of the first insulator layer 12A beyond the metal layer 15 from the upper surface of the second insulator layer 12B. The first pad 13a and the second pad 14a are formed on the upper surfaces of the first electrode 13 and the second electrode 14, respectively, to secure the flat surface for connection. The first pad 13a and the second pad 14a may be plated. The first pad 13a and the second pad 14a are higher than the upper surface of the second insulator layer 12B. The second insulator layer 12B may also be made of silicon oxide, silicon nitride, or the like, similarly to the first insulator layer 12A.

In the semiconductor light-receiving element 10 according to the fourth embodiment, the metal layer 15 is formed on the upper surface of the first insulator layer 12A so as to cover the semiconductor laminate 20 and the wirings 16. Therefore, the semiconductor laminate 20 and the wirings 16 of the semiconductor light-receiving element 10 are electrically shielded, and electromagnetic interference from the semiconductor laminate 20 and the wirings 16 is prevented from reaching the transimpedance amplifier 50. Therefore, deterioration of reception sensitivity caused by the noise current due to interference is suppressed, and space saving of the mounting area can be achieved by flip-chip mounting the semiconductor light-receiving element 10 on the transimpedance amplifier 50.

In addition, the fourth embodiment further has the second insulator layer 12B covering the metal layer 15. Since the second insulator layer 12B is interposed between the transimpedance amplifier 50 and the metal layer 15 when the semiconductor light-receiving element 10 is flip-chip mounted on the transimpedance amplifier 50, electrical interference due to a high frequency component from the transimpedance amplifier 50 reflected by the metal layer 15 can be suppressed.

A manufacturing method of the semiconductor light-receiving element 10 according to the fourth embodiment will be described. The semiconductor laminate 20 deposited on the upper surface of the semiconductor substrate 11 is processed into a desired shape by wet etching or the like, and the first semiconductor electrode 24 and the second semiconductor electrode 25 are formed on the semiconductor laminate 20. The mirror or the like for returning the incident light 102 may be formed on the upper surface of the semiconductor laminate 20. Subsequently, a part of the first insulator layer 12A is formed on the upper surface of the semiconductor substrate 11 so as to cover the semiconductor laminate 20. Further, after the first electrode 13, the second electrode 14, and the wirings 16 are formed by plating, vapor deposition, or the like, the remaining part of the first insulator layer 12A is formed on the upper parts. In the first insulator layer 12A, the upper parts of the first electrode 13 and the second electrode 14 are removed by dry etching, or the like. The metal layer 15, the first pad 13a, and the second pad 14a are formed by plating, vapor deposition, or the like. The first pad 13a and the second pad 14a are formed on the upper surfaces of the first electrode 13 and the second electrode 14, and made higher than the upper surface of the metal layer 15. Finally, the second insulator layer 12B is formed so as to cover the first insulator layer 12A and the metal layer 15.

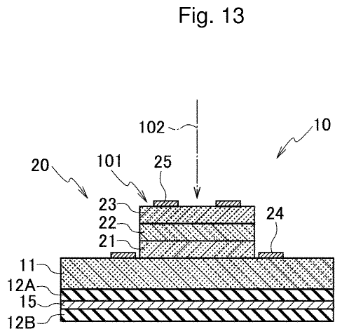

FIG. 13 is a cross-sectional view showing a semiconductor light-receiving element 10 according to a modification example of the fourth embodiment. The semiconductor light-receiving element 10 according to the modification example is the front surface incident type for receiving incident light 102 incident from above. The semiconductor light-receiving element 10 according to the modification example has the semiconductor substrate 11, and the semiconductor laminate 20 in which the first semiconductor layer 21 having a first conductivity type, the light absorption layer 22 made of a semiconductor, and the second semiconductor layer 23 having a second conductivity type are sequentially laminated on the upper surface of the semiconductor substrate 11. The semiconductor laminate 20 constitutes the pin photodiode.

In the semiconductor laminate 20, the light absorption layer 22 may be composed of a semiconductor having band gap energy corresponding to a wavelength of target light. The first semiconductor layer 21 and the second semiconductor layer 23 may be composed of a semiconductor having band gap energy larger than that of the semiconductor constituting the light absorption layer 22. The first semiconductor layer 21 and the second semiconductor layer 23 are each of conductivity types by introducing impurities, and the light absorption layer 22 may be in a state where the impurity concentration is lower than that of the first semiconductor layer 21 and the second semiconductor layer 23.

The semiconductor substrate 11 may be composed of semi-insulating InP. The first semiconductor layer 21 may be composed of n⁺-InP into which the n-type impurity is introduced with the high concentration. The light absorption layer 22 may be composed of undoped InGaAs. The second semiconductor layer 23 may be composed of p⁺-InGaAsP into which the p-type impurity is introduced with the high concentration. In these cases, the above-described first conductivity type becomes n-type and second conductivity type becomes p-type. The light absorption layer 22 and the second semiconductor layer 23 may be patterned into a predetermined shape, a part of the upper surface of the first semiconductor layer 21 may be exposed, and the first semiconductor electrode 24 may be formed in the exposed region. The second semiconductor electrode 25 is formed on the upper surface of the second semiconductor layer 23.

The semiconductor light-receiving element 10 according to the modification example further has the first insulator layer 12A, the metal layer 15, and the second insulator layer 12B sequentially laminated on the lower surface of the semiconductor substrate 11. The metal layer 15 is formed so as to cover the semiconductor laminate 20 and the wirings 16.

A manufacturing method of the semiconductor light-receiving element 10 according to the modification example will be described. On the upper surface of the semiconductor substrate 11, the deposited semiconductor laminate 20 is processed into a desired shape by wet etching or the like to form the first semiconductor electrode 24 and the second semiconductor electrode 25. On the lower surface of the semiconductor substrate 11, after the first insulator layer 12A is formed, the metal layer 15 is formed by vapor deposition, plating, or the like, and the second insulator layer 12B is further formed. The lower surface of the second insulator layer 12B is installed on the upper surface of the transimpedance amplifier 50. Then, the first semiconductor electrode 24 and the second semiconductor electrode 25 are connected to the input terminals 51 of the transimpedance amplifier 50 by the wires 32.

The semiconductor light-receiving element 10 of the modification example is mounted so that the lower surface of the metal layer 15 faces the upper surface of the transimpedance amplifier 50. Then, the first semiconductor electrode 24 and the second semiconductor electrode 25 are connected to the input terminals of the transimpedance amplifier 50 by the wires, respectively. Therefore, also in the semiconductor light-receiving element 10 according to the modification example, the semiconductor laminate 20 is electrically shielded by the intervening metal layer 15, and electromagnetic interference from the semiconductor laminate 20 is prevented from reaching the transimpedance amplifier 50. Therefore, deterioration of reception sensitivity caused by the noise current due to interference is suppressed.

In addition, the modification example further has the second insulator layer 12B covering the metal layer 15. Since the second insulator layer 12B is interposed between the transimpedance amplifier 50 and the metal layer 15 when the semiconductor light-receiving element 10 is flip-chip mounted on the transimpedance amplifier 50, electrical interference due to the high frequency component from the transimpedance amplifier 50 reflected by the metal layer 15 can be suppressed.

### REFERENCE SIGNS LIST

11 Semiconductor substrate
12 First insulator layer
13 First electrode
14 Second electrode
15 Metal layer
16 Wiring
20 Semiconductor laminate
21 First semiconductor layer
22 Light absorption layer
23 Second semiconductor layer
50 Transimpedance amplifier

1. A semiconductor light-receiving element comprising:
a semiconductor laminate formed on an upper surface of a semiconductor substrate and in which a first semiconductor layer having a first conductivity type, a light absorption layer made of a semiconductor, and a second semiconductor layer having a second conductivity type are sequentially laminated;
a first insulator layer formed on the upper surface of the semiconductor substrate so as to cover the semiconductor laminate;
a first electrode and a second electrode formed on the upper surface of the first insulator layer;
wirings connecting the first electrode and the second electrode to the first semiconductor layer and the second semiconductor layer, respectively; and
a metal layer formed on the upper surface of the first insulator layer so as to cover the semiconductor laminate and the wirings and electrically separated from the first electrode and the second electrode.

2. The semiconductor light-receiving element according to claim 1, further comprising:
a first pad and a second pad formed on the upper surface of the first electrode and the second electrode so as to be higher than the upper surface of the metal layer, respectively, wherein
the metal layer is formed so as to be electrically separated from the first pad and the second pad also.

3. The semiconductor light-receiving element according to claim 2, further comprising:
a third pad formed on the upper surface of the first insulator layer and having the same height as the first pad and the second pad, wherein
the metal layer is formed so as to be electrically separated from the third pad also.

4. The semiconductor light-receiving element according to claim 2, further comprising:
a second insulator layer formed on the upper surface of the first insulator layer so as to cover the metal layer, wherein
the first pad and the second pad are formed so as to be higher than the upper surface of the second insulator layer.

5. A semiconductor light-receiving element comprising:
a semiconductor laminate formed on an upper surface of a semiconductor substrate and in which a first semiconductor layer having a first conductivity type, a light absorption layer made of a semiconductor, and a second semiconductor layer having a second conductivity type are sequentially laminated;
a first insulator layer formed so as to cover a lower surface of the semiconductor substrate; and
a metal layer formed on the lower surface of the first insulator layer so as to cover the semiconductor laminate and the wirings connected to the semiconductor laminate.

6. The semiconductor light-receiving element according to claim 5, further comprising:
a pad formed on the lower surface of the metal layer and having a predetermined height.

7. The semiconductor light-receiving element according to claim 5, further comprising:
a second insulator layer formed so as to cover the lower surface of the metal layer.

8. The semiconductor light-receiving element according to claim 1, further comprising:
a through via connected to the metal layer and penetrating through the semiconductor substrate, the first insulator layer, and the metal layer.

9. The semiconductor light-receiving element according to claim 5, further comprising:
a through via connected to the metal layer and penetrating through the semiconductor substrate, the first insulator layer, and the metal layer.
